(19) United States
(12) Patent Application Publication
(10) Pub. No.: US 2023/0320226 A1
(43) Pub. Date: Oct. 5, 2023

(54) Piezoelectric Element And Piezoelectric Element Application Device

(71) Applicant: SEIKO EPSON CORPORATION, Tokyo (JP)

(72) Inventors: Kazuya KITADA, Matsumoto (JP); Koji OHASHI, Matsumoto (JP); Yasuaki HAMADA, Chino (JP); Yoshiki YANO, Chino (JP)

(21) Appl. No.: 18/192,840

(22) Filed: Mar. 30, 2023

(30) Foreign Application Priority Data
Mar. 31, 2022 (JP) 2022-058949

(51) Int. Cl. H01L 41/00; B41J 2/14

(52) U.S. Cl. CPC H10N 30/871; H10N 30/85; B41J 2/14233; B41J 2002/14258

(57) ABSTRACT

A piezoelectric element according to the present disclosure includes: a substrate; a first electrode formed on the substrate; a piezoelectric layer formed on the first electrode; and a second electrode formed on the piezoelectric layer, in which the piezoelectric layer contains potassium, sodium, niobium, oxygen, and carbon, and in secondary ion mass spectrometry in the piezoelectric layer, a ratio of a maximum intensity of carbon to a maximum intensity of oxygen is 3.1×10⁻³ or more and 9.1×10⁻³ or less.

The present application is based on, and claims priority from JP Application Serial Number 2022-058949, filed Mar. 31, 2022, the disclosure of which is hereby incorporated by reference herein in its entirety.

### BACKGROUND

### 1. Technical Field

The present disclosure relates to a piezoelectric element and a piezoelectric element application device.

### 2. Related Art

A piezoelectric element generally includes a substrate, a piezoelectric layer having an electromechanical conversion characteristic, and two electrodes sandwiching the piezoelectric layer. In recent years, development of devices (piezoelectric element application devices) using such a piezoelectric element as a driving source has been actively performed. One of the piezoelectric element application devices is a liquid ejection head represented by an ink jet recording head, a MEMS element represented by a piezoelectric MEMS element, an ultrasonic measurement device represented by an ultrasonic sensor, and further, a piezoelectric actuator device.

Lead zirconate titanate (PZT) is known as a material (piezoelectric material) for a piezoelectric layer of a piezoelectric element. In recent years, non-lead-based piezoelectric materials having a reduced lead content have been developed from the viewpoint of environmental loading reduction.

Further, in recent years, there has been a strong demand for further size reduction and higher performance of various electronic devices, electronic components, and the like, and accordingly, size reduction and higher performance of piezoelectric elements have also been demanded.

As one of the non-lead-based piezoelectric materials, for example, potassium sodium niobate (KNN; (K,Na)NbO₃) has been proposed as in JP-A-2009-130182 and JP-A-2014-107563.

Specifically, JP-A-2009-130182 discloses a piezoelectric thin film element which contains potassium, sodium, and niobium as main components of a piezoelectric layer and in which a current blocking layer is provided between a lower electrode layer and an upper electrode layer.

JP-A-2014-107563 discloses a piezoelectric element including a piezoelectric layer which is a potassium sodium niobate thin film. JP-A-2014-107563 discloses that the piezoelectric layer includes at least one first piezoelectric layer substantially not containing Mn and at least one second piezoelectric layer containing Mn.

As described above, the piezoelectric element (KNN-based piezoelectric element) using KNN as one of non-lead-based piezoelectric materials has been proposed. However, when a piezoelectric layer containing KNN is thinned, insulation is lowered, and it may be difficult to obtain excellent piezoelectric characteristics (in particular, leakage characteristics) as a piezoelectric element.

In contrast, JP-A-2009-130182 discloses a piezoelectric element in which a material having high insulation is disposed between the piezoelectric layer and an upper electrode. However, in the piezoelectric element according to JP-A-2009-130182, since insulation of the piezoelectric layer itself including KNN is not improved, a material other than KNN is interposed between the upper electrode and a lower electrode, which may reduce a displacement amount of the piezoelectric element.

Although JP-A-2014-107563 discloses the piezoelectric element in which Mn is added to the piezoelectric layer, it is difficult to provide sufficient insulation in the piezoelectric layer because Mn is contained only in a part of a piezoelectric film.

In view of such circumstances, in the KNN-based piezoelectric element, a piezoelectric layer having excellent insulation is required.

Such a problem is not limited to a piezoelectric element used in a piezoelectric actuator mounted on a liquid ejection head represented by an ink jet recording head, but similarly in a piezoelectric element used in another piezoelectric element application device.

### SUMMARY

A first aspect of the present disclosure provides a piezoelectric element including: a substrate; a first electrode formed on the substrate; a piezoelectric layer formed on the first electrode; and a second electrode formed on the piezoelectric layer, in which the piezoelectric layer contains potassium, sodium, niobium, oxygen, and carbon, and in secondary ion mass spectrometry in the piezoelectric layer, a ratio of a maximum intensity of carbon to a maximum intensity of oxygen is 3.1×10⁻³ or more and 9.1×10⁻³ or less.

Another aspect of the present disclosure provides a piezoelectric element application device including: the piezoelectric element according to the above aspect.

### BRIEF DESCRIPTION OF THE DRAWINGS

FIG. 1 is a perspective view showing a schematic configuration of a recording device according to a first embodiment.

FIG. 2 is an exploded perspective view of a recording head of the recording device in FIG. 1.

FIG. 3 is a plan view of the recording head of the recording device in FIG. 1.

FIG. 4 is a cross-sectional view of the recording head of the recording device in FIG. 1.

FIG. 5 is an enlarged cross-sectional view taken along a line B-B′ in FIG. 4.

### DESCRIPTION OF EXEMPLARY EMBODIMENTS

Hereinafter, an embodiment of the present disclosure will be described with reference to the drawings. The following description shows an aspect of the present disclosure, and can be freely changed without departing from the gist of the present disclosure. In the drawings, the same reference signs denote the same members, and the description thereof is omitted as appropriate. The number after a letter which makes up the reference sign is referenced by a reference sign which includes the same letter and is used to distinguish between elements which have similar configurations. When it is not necessary to distinguish elements indicated by the reference signs which include the same letter from each other, each of the elements is referenced by a reference sign containing only a letter.

In each drawing, X, Y, and Z represent three spatial axes orthogonal to one another. In the present description, directions along these axes are referred to as a first direction X (X direction), a second direction Y (Y direction), and a third direction Z (Z direction), respectively, a direction of an arrow in each drawing is referred to as a positive (+) direction, and a direction opposite from the arrow is referred to as a negative (−) direction. The X direction and the Y direction represent in-plane directions of a plate, a layer, and a film, and the Z direction represents a thickness direction or a stacking direction of a plate, a layer, and a film.

Components shown in each drawing, that is, a shape and size of each part, a thickness of a plate, a layer, and a film, a relative positional relation, a repeating unit, and the like may be exaggerated for describing the present disclosure. Furthermore, the term “on” in the present description does not limit that a positional relation between the components is “directly on”. For example, expressions such as “a first electrode on a substrate” and “a piezoelectric layer on the first electrode”, which will be described later, do not exclude those including other components between the substrate and the first electrode or between the first electrode and the piezoelectric layer.

### Piezoelectric Element Application Device

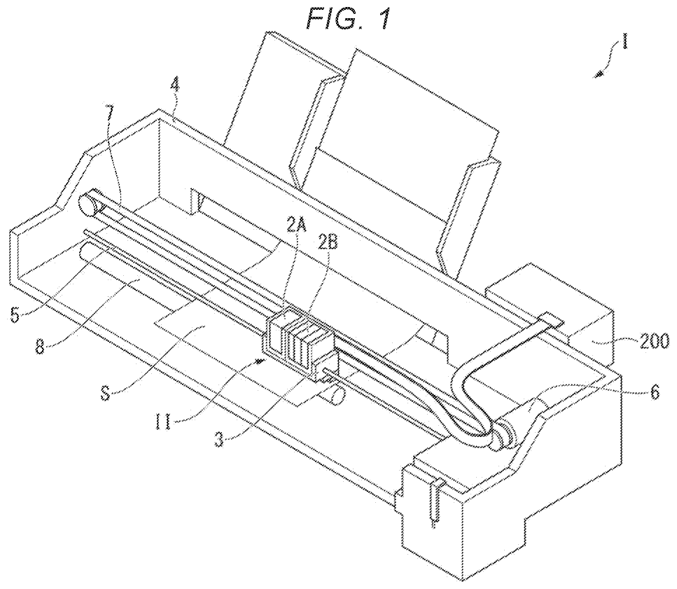

First, an ink jet recording device, which is an example of a liquid ejection device including a recording head according to an embodiment of the present disclosure, will be described with reference to the drawings. The liquid ejection device is an example of a piezoelectric element application device. FIG. 1 is a perspective view showing a schematic configuration of the ink jet recording device.

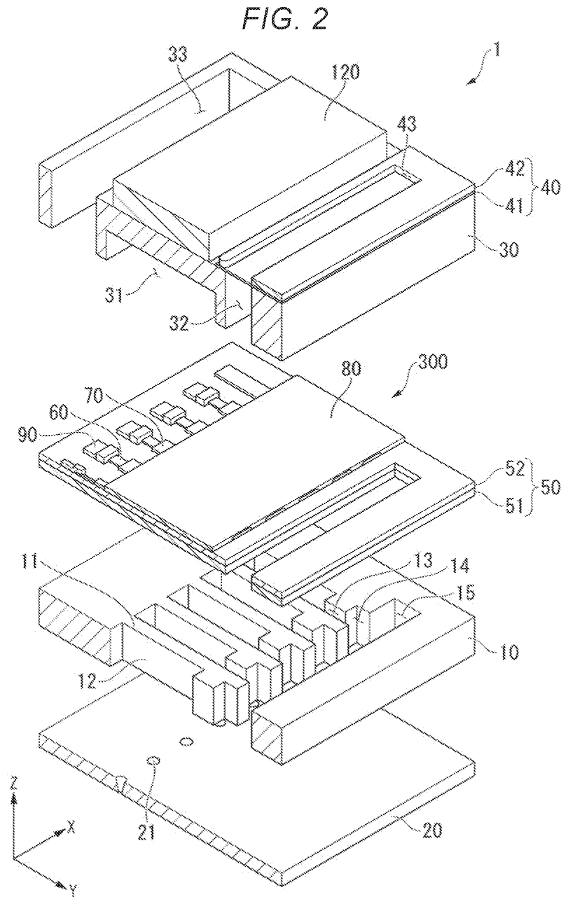

As shown in FIG. 1, in an ink jet recording device (recording device) I, an ink jet recording head unit (head unit) II is detachably provided in cartridges 2A and 2B. The cartridges 2A and 2B constitute an ink supply unit. The head unit II includes a plurality of ink jet recording heads (recording heads) 1 (see FIG. 2 and the like), and is mounted on a carriage 3. The carriage 3 is movable in an axial direction on a carriage shaft 5 attached to a device main body 4. The head unit II and the carriage 3 can eject, for example, a black ink composition and a color ink composition, respectively.

A driving force of a drive motor 6 is transmitted to the carriage 3 via a plurality of gears (not shown) and a timing belt 7, so that the carriage 3 on which the head unit II is mounted is moved along the carriage shaft 5. On the other hand, the device main body 4 is provided with a conveyance roller 8 as a conveyance unit, and a recording sheet S which is a recording medium (media) such as paper is conveyed by the conveyance roller 8. The conveyance unit which conveys the recording sheet S is not limited to a conveyance roller, and may be a belt, a drum, or the like.

In the recording head (head chip) 1, a piezoelectric element 300 (see FIG. 2 and the like), which will be described in detail later, is used as a piezoelectric actuator device. By using the piezoelectric element 300, it is possible to avoid deterioration of various characteristics (piezoelectric characteristics, durability, ink ejection characteristics, and the like) in the recording device I. The piezoelectric element application device according to the embodiment can particularly improve piezoelectric characteristics (in particular, leakage characteristics) by applying the piezoelectric element 300 to be described later.

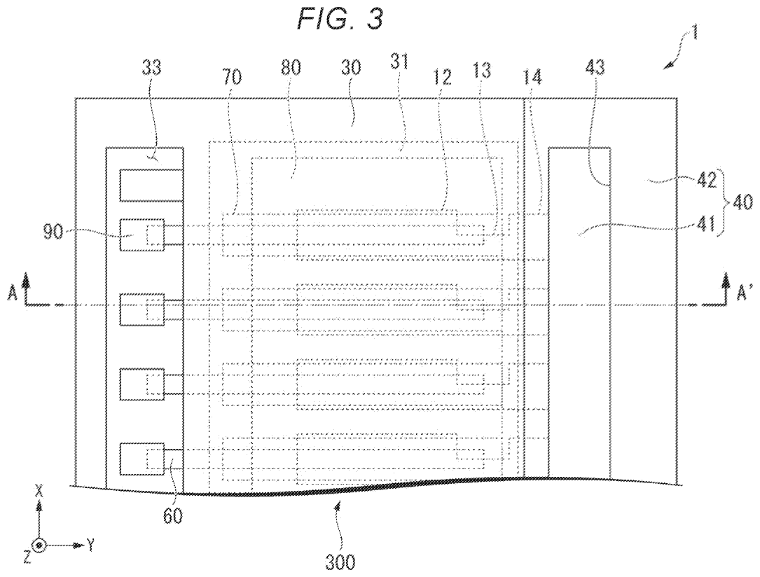

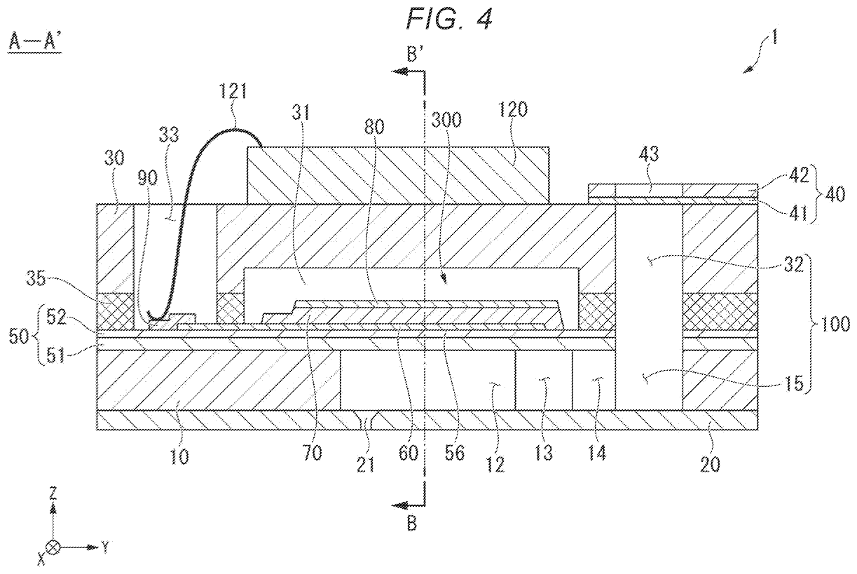

Next, the recording head (head chip) 1, which is an example of the head chip mounted on the liquid ejection device, will be described with reference to the drawings. FIG. 2 is an exploded perspective view showing a schematic configuration of the ink jet recording head. FIG. 3 is a plan view showing the schematic configuration of the ink jet recording head. FIG. 4 is a cross-sectional view taken along a line A-A′ in FIG. 3. FIGS. 2 to 4 each show a part of a configuration of the recording head 1, and are omitted as appropriate.

As shown in FIG. 2, the recording head (head chip) 1 includes a nozzle plate 20 having nozzle openings 21 for ejecting liquid droplets, pressure generation chambers 12 communicating with the nozzle openings 21, partition walls 11 provided on the nozzle plate 20 and forming the pressure generation chambers 12, a flow path forming substrate (substrate) 10 forming a part of wall surfaces of the pressure generation chambers 12, the piezoelectric element 300 provided on the substrate 10; and lead electrodes (voltage application portions) 90 which apply voltages to the piezoelectric element 300.

A plurality of partition walls 11 are formed in the substrate 10. A plurality of pressure generation chambers 12 are partitioned by the partition walls 11. That is, in the substrate 10, the pressure generation chambers 12 are arranged side by side along the X direction (a direction in which the nozzle openings 21 for ejecting ink of the same color are arranged side by side). As the substrate 10, for example, a silicon single crystal substrate can be used.

In the substrate 10, ink supply paths 13 and communication paths 14 are formed at one end portion side (+Y direction side) of each of the pressure generation chambers 12. Each of the ink supply paths 13 is formed such that an area of an opening at the one end portion side of the pressure generation chamber 12 is reduced. Each of the communication paths 14 has substantially the same width as the pressure generation chamber 12 in a +X direction. A communication portion 15 is formed at an outer side (+Y direction side) of the communication path 14. The communication portion 15 constitutes a part of a manifold 100. The manifold 100 serves as a common ink chamber for each pressure generation chamber 12. Thus, a liquid flow path including the pressure generation chamber 12, the ink supply path 13, the communication path 14, and the communication portion 15 is formed in the substrate 10.

On one surface (a surface on a −Z direction side) of the substrate 10, the nozzle plate 20 made of, for example, SUS is bonded. In the nozzle plate 20, the nozzle openings 21 are arranged side by side along the +X direction. The nozzle openings 21 communicate with the pressure generation chambers 12. The nozzle plate 20 can be bonded to the substrate 10 by an adhesive, a thermal welding film, or the like.

A diaphragm 50 is formed on the other surface (a surface at a +Z direction side) of the substrate 10. The diaphragm 50 includes, for example, an elastic film 51 formed on the substrate 10 and an insulator film 52 formed on the elastic film 51. The elastic film 51 is made of, for example, silicon dioxide (SiO₂), and the insulator film 52 is made of, for example, zirconium oxide (ZrO₂). The elastic film 51 may not be a separate member from the substrate 10. A part of the substrate 10 may be processed to be thin and used as the elastic film 51. The elastic film 51 is not limited to SiO₂, and may be a film made of aluminum oxide (Al₂O₃), tantalum oxide (V) (Ta₂O₅), silicon nitride (SiN), and the like. The insulator film 52 has a function as a stopper for preventing potassium and sodium, which are constituent elements of piezoelectric layers 70, from passing through first electrodes 60 and reaching the substrate 10 when the piezoelectric layers 70 to be described later are formed.

The first electrodes 60 are provided for the pressure generation chamber 12. That is, each of the first electrodes 60 is provided as an individual electrode for the pressure generation chamber 12. The first electrode 60 has a width smaller than a width of the pressure generation chamber 12 in the +X direction and in a −X direction. The first electrode 60 has a width larger than a width of the pressure generation chamber 12 in the +Y direction and in a −Y direction. That is, in the +Y direction and in the −Y direction, both end portions of the first electrode 60 are formed up to an outside of a region on the diaphragm 50 facing the pressure generation chamber 12. At one end portion side (an opposite side from the communication path 14) of the first electrode 60, the lead electrodes (voltage application portions) 90 which apply voltages to the piezoelectric element 300 are coupled.

Each of the piezoelectric layers 70 is provided between the first electrode 60 and a second electrode 80. The piezoelectric layer 70 is a thin-film piezoelectric substance. The piezoelectric layer 70 has a width larger than the width of the first electrode 60 in the +X direction and in the −X direction. The piezoelectric layer 70 has a width larger than a length of the pressure generation chamber 12 in the +Y direction and in the −Y direction. An end portion of the piezoelectric layer 70 at an ink supply path 13 side (+Y direction side) is formed up to an outside of an end portion of the first electrode 60 at the +Y direction side. That is, the end portion of the first electrode 60 at the +Y direction side is covered with the piezoelectric layer 70. On the other hand, an end portion of the piezoelectric layer 70 at a lead electrode 90 side (−Y direction side) is at an inner side (+Y direction side) of an end portion of the first electrode 60 at the −Y direction side. That is, the end portion of the first electrode 60 at the −Y direction side is not covered with the piezoelectric layer 70.

The second electrode 80 is continuously provided on the piezoelectric layer 70 and the diaphragm 50 over the +X direction. That is, the second electrode 80 is configured as a common electrode common to the plurality of piezoelectric layers 70. In the embodiment, the first electrode 60 constitutes an individual electrode provided independently corresponding to the pressure generation chamber 12, and the second electrode 80 constitutes a common electrode provided continuously in a direction in which the pressure generation chambers 12 are arranged side by side. Alternatively, the first electrode 60 may constitute the common electrode, and the second electrode 80 may constitute the individual electrode.

In the embodiment, the diaphragm 50 and the first electrode 60 are displaced by displacement of the piezoelectric layer 70 having an electromechanical conversion characteristic. That is, the diaphragm 50 and the first electrode 60 substantially function as a diaphragm. In practice, since the second electrode 80 is also displaced due to displacement of the piezoelectric layer 70, a region in which the diaphragm 50, the first electrode 60, the piezoelectric layer 70, and the second electrode 80 are sequentially stacked functions as a movable portion (also referred to as a vibration portion) of the piezoelectric element 300.

In the embodiment, either the elastic film 51 or the insulator film 52 may be omitted so that the remaining one functions as the diaphragm, or the elastic film 51 and insulator film 52 may be omitted so that only the first electrode 60 functions as the diaphragm.

On the substrate 10 (diaphragm 50) on which the piezoelectric element 300 is formed, a protective substrate 30 is bonded by an adhesive 35. The protective substrate 30 has a manifold portion 32. At least a portion of the manifold 100 is implemented by the manifold portion 32. The manifold portion 32 according to the embodiment penetrates the protective substrate 30 in the thickness direction (Z direction), and is further formed over a width direction (+X direction) of the pressure generation chamber 12. The manifold portion 32 communicates with the communication portion 15 in the substrate 10. With these configurations, the manifold 100, which is the common ink chamber for each pressure generation chamber 12, is formed.

The protective substrate 30 has a piezoelectric element holding portion 31 formed in a region including the piezoelectric element 300. The piezoelectric element holding portion 31 has enough space not to interfere with movement of the piezoelectric element 300. This space may or may not be sealed. The protective substrate 30 is provided with a through hole 33 penetrating the protective substrate 30 in the thickness direction (Z direction). An end portion of each of the lead electrodes 90 is exposed in the through hole 33.

Examples of a material for the protective substrate 30 include Si, SOI, glass, a ceramic material, a metal, and a resin, and it is more preferable that the protective substrate 30 is formed of a material having substantially the same coefficient of thermal expansion as that of the substrate 10.

A drive circuit 120 functioning as a signal processing unit is fixed on the protective substrate 30. As the drive circuit 120, for example, a circuit board or a semiconductor integrated circuit (IC) can be used. The drive circuit 120 and the lead electrode 90 are electrically coupled to each other via a coupling wiring 121 made of a conductive wire such as a bonding wire inserted through the through hole 33. The drive circuit 120 can be electrically coupled to a printer controller 200 (see FIG. 1). Such a drive circuit 120 functions as a control unit for the piezoelectric actuator device (piezoelectric element 300).

On the protective substrate 30, a compliance substrate 40 including a sealing film 41 and a fixing plate 42 is bonded. The sealing film 41 is made of a material having low rigidity, and the fixing plate 42 can be made of a hard material such as a metal. A region of the fixing plate 42 facing the manifold 100 is an opening 43 with a part completely removed in the thickness direction (Z direction). One surface (a surface at a +Z direction side) of the manifold 100 is sealed only with the sealing film 41 having flexibility.

Such a recording head 1 ejects ink droplets by the following operation.

First, ink is taken in from an ink introduction port coupled to an external ink supply unit (not shown), and an inside of the recording head 1 is filled with ink from the manifold 100 to the nozzle openings 21. Thereafter, according to a recording signal from the drive circuit 120, a voltage is applied between the first electrode 60 and the second electrode 80 corresponding to each pressure generation chamber 12, and the piezoelectric element 300 is deflected and deformed. Accordingly, a pressure in each pressure generation chamber 12 is increased, and ink droplets are ejected from the nozzle openings 21.

### Piezoelectric Element

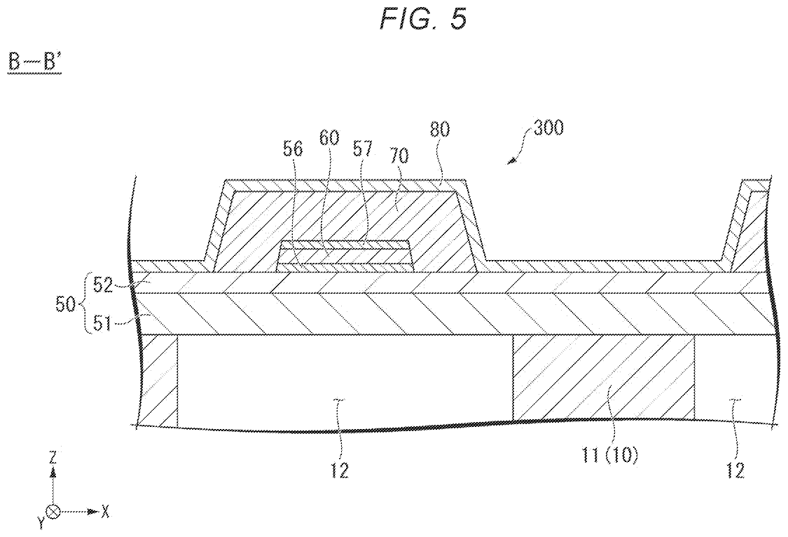

Next, a configuration of the piezoelectric element 300 will be described with reference to the drawings. FIG. 5 is an enlarged cross-sectional view taken along a line B-B′ in FIG. 4.

As shown in the drawing, the piezoelectric element 300 includes the substrate 10, the first electrode 60 formed on the substrate 10, the piezoelectric layer 70 formed on the first electrode 60 and containing potassium, sodium, niobium, oxygen, and carbon, and the second electrode 80 formed on the piezoelectric layer 70.

The substrate 10 is provided with pressure generation chambers 12 partitioned by a plurality of partition walls 11. With such a configuration, the movable portion of the piezoelectric element 300 is formed. Thicknesses of the elements described herein are merely examples, and can be changed without departing from the scope of the present disclosure.

A material for the first electrode 60 and a material for the second electrode 80 are preferably a noble metal such as platinum (Pt) or iridium (Ir) or an oxide thereof. The material for the first electrode 60 and the material for the second electrode 80 may be any material having conductivity. The material for the first electrode 60 and the material for the second electrode 80 may be the same or different.

The substrate 10 is, for example, a flat plate formed of a semiconductor or an insulator. The substrate 10 may be a single layer or a structure in which a plurality of layers are stacked.

As described above, the diaphragm 50 including the elastic film 51 and the insulator film 52 is formed on the other surface (a surface at the +Z direction side) of the substrate 10. The elastic film 51 is made of, for example, silicon dioxide (SiO₂), and the insulator film 52 is made of, for example, zirconium oxide (ZrO₂).

The first electrode 60 is formed on the substrate 10 (the diaphragm 50 in FIG. 5). A shape of the first electrode 60 is, for example, a layer shape or a thin film shape. A thickness (a length in a Z-axis direction) of the first electrode 60 is, for example, 10 nm or more and 200 nm or less. A planar shape (a shape viewed from the Z-axis direction) of the first electrode 60 is not particularly limited as long as the piezoelectric layer 70 can be disposed between the first electrode 60 and the second electrode 80 when the second electrode 80 faces the first electrode 60.

Examples of the material for the first electrode 60 include various metals such as nickel, iridium, and platinum, conductive oxides thereof (for example, iridium oxide), a composite oxide of strontium and ruthenium (SrRuOx:SRO), and a composite oxide of lanthanum and nickel (LaNiOx:LNO). The first electrode 60 may have a single-layer structure of the materials shown above, or may have a structure in which a plurality of materials are stacked.

The first electrode 60 can be paired with the second electrode 80 and serve as one electrode (for example, a lower electrode formed below the piezoelectric layer 70) for applying a voltage to the piezoelectric layer 70.

The diaphragm 50 may be omitted, and the first electrode 60 may also function as a diaphragm. That is, the first electrode 60 may have a function as one electrode for applying a voltage to the piezoelectric layer 70 and a function as a diaphragm which can be deformed by fluctuation in the piezoelectric layer 70.

An adhesion layer 56 may be provided between the first electrode 60 and the insulator film 52. The adhesion layer 56 is made of, for example, titanium oxide (TiOₓ), titanium (Ti), or SiN, and has a function of improving adhesion between the piezoelectric layer 70 and the diaphragm 50. When a titanium oxide (TiOₓ) layer, a titanium (Ti) layer, or a silicon nitride (SiN) layer is used as the adhesion layer, the adhesion layer 56, like the insulator film 52 described earlier, also functions as a stopper for preventing potassium and sodium, which are the constituent elements of the piezoelectric layer 70, from passing through the first electrode 60 and reaching the substrate 10 when the piezoelectric layer 70 to be described later is formed. The adhesion layer 56 may be omitted.

For example, a seed layer (orientation control layer) 57 is preferably provided between the first electrode 60 and the piezoelectric layer 70. The seed layer has a function of controlling orientation of a crystal of the piezoelectric substance constituting the piezoelectric layer 70. That is, by providing the seed layer 57 on the first electrode 60, a crystal of the piezoelectric substance constituting the piezoelectric layer 70 can be preferentially oriented in predetermined orientation (for example, (100) plane). By increasing crystal orientation of the piezoelectric layer, it is possible to efficiently utilize domain rotation and improve displacement characteristics. Examples of a material for the seed layer 57 include various metals such as titanium, nickel, iridium, and platinum, oxides thereof, and compounds containing bismuth, iron, titanium, and lead.

The piezoelectric layer 70 is formed on the first electrode 60. The piezoelectric layer 70 is a composite oxide having a perovskite structure represented by a general formula ABO₃, and contains a piezoelectric material made of a KNN-based composite oxide represented by the following formula (1).

(K_{X},Na_{1-X})NbO₃ (1)
(0.1≤X≤0.9)

A composite oxide represented by the above formula (1) is a so-called KNN-based composite oxide. Since the KNN-based composite oxide is a non-lead-based piezoelectric material in which a content of lead (Pb) or the like is reduced, the KNN-based composite oxide is excellent in biocompatibility and has low environmental loading. In addition, since the KNN-based composite oxide is excellent in piezoelectric characteristics among non-lead-based piezoelectric materials, it is advantageous for improving various characteristics.

In the embodiment, in secondary ion mass spectrometry (SIMS analysis) for the piezoelectric layer 70, a ratio of a maximum intensity of carbon to a maximum intensity of oxygen is 3.1×10⁻³ or more and 9.1×10⁻³ or less.

The inventors examined insulation of the piezoelectric layer 70, and found that when a carbon concentration in a KNN material constituting the piezoelectric layer 70 is high, leakage characteristics deteriorate. That is, in order to improve the insulation in the piezoelectric layer 70 and obtain excellent leakage characteristics, it is effective to reduce a concentration of carbon as an impurity in the piezoelectric layer 70. Specifically, in the SIMS analysis, it was found that when the ratio of the maximum intensity of carbon to the maximum intensity of oxygen is 3.1×10⁻³ or more and 9.1×10⁻³ or less, the insulation of the piezoelectric layer 70 can be improved.

In the embodiment, a specific unit which reduces the carbon concentration in the piezoelectric layer 70 is not particularly limited, and for example, it is effective to include lithium (Li) in the piezoelectric layer 70, to reduce generation of vacancies in the piezoelectric layer 70, or to add a polyester-based alcohol polymer material to a precursor solution used at the time of deposition of the piezoelectric layer 70.

Addition of a first transition metal is effective in reducing the vacancies generated in the piezoelectric layer 70. By including the first transition metal in the piezoelectric layer 70, the vacancies in the piezoelectric layer 70 are filled with the first transition metal, and thus the insulation of the piezoelectric layer 70 can be further improved. As such a first transition metal, manganese (Mn), copper (Cu), and cobalt (Co) are preferable. In particular, manganese (Mn) and copper (Cu) are effective, and a leakage current in the piezoelectric layer 70 can be reduced when the piezoelectric layer 70 contains Mn or/and Cu. When Mn is contained, a content is preferably from 0.1 mol % to 2.0 mol % with respect to a total amount of elements constituting the piezoelectric layer 70. When copper (Cu) is contained, a content is similarly from 0.1 mol % to 2.0 mol %. The number of kinds of the first transition metals in the piezoelectric layer 70 may be two or more, and in this case, a total content of the first transition metals may be 0.1 mol % or more and 5 mol % or less.

The carbon concentration and an oxygen concentration in the piezoelectric layer 70 can be measured by, for example, a general SIMS analysis. In the SIMS analysis, there is no guarantee that a correct concentration profile can be obtained in the vicinity of a surface of a sample to be measured and in the vicinity of an interface with a layer adjacent to the sample. Therefore, in the embodiment, a SIMS analysis is performed in a region 50 nm from each interface with the first electrode 60 and the second electrode 80 adjacent to the piezoelectric layer 70, or a region excluding ¼ of a thickness of the piezoelectric layer 70 on an interface side.

The piezoelectric layer 70 in the embodiment is preferably made of polycrystals preferentially oriented to the (100) plane. By preferentially orienting the piezoelectric layer 70 to the (100) plane in this way, it is possible to efficiently utilize the domain rotation and improve the displacement characteristics. The thickness of the piezoelectric layer 70 is, for example, 50 nm or more and 2000 nm or less.

The term “preferentially oriented to the (100) plane” includes a case where all crystals in the piezoelectric layer 70 are oriented to the (100) plane and a case where most of the crystals (50% or more, preferably 80% or more, and more preferably 90% or more of the crystals) are oriented to the (100) plane.

When the piezoelectric layer 70 is made of polycrystals, a stress in the plane is dispersed and equalized. Therefore, a stress fracture of the piezoelectric element 300 is less likely to occur, and reliability of an element is improved.

The piezoelectric material constituting the piezoelectric layer 70 may be a KNN-based composite oxide, and is not limited to a composition represented by the above formula (1). For example, another metal element (additive) may be contained in a A site or a B site of potassium sodium niobate. Examples of such additives include manganese (Mn), lithium (Li), barium (Ba), calcium (Ca), strontium (Sr), zirconium (Zr), titanium (Ti), bismuth (Bi), tantalum (Ta), antimony (Sb), iron (Fe), cobalt (Co), silver (Ag), magnesium (Mg), zinc (Zn) and copper (Cu). Among these examples, as described above, lithium (Li) is preferably contained. When lithium is contained in the piezoelectric layer 70, an amount of carbon in the piezoelectric layer 70 can be reduced. From such a viewpoint, a content of lithium is preferably 1 mol % or more with respect to a total amount of metal elements constituting the piezoelectric layer 70. In consideration of piezoelectric characteristics ensured by other elements, the content of lithium is preferably 10 mol % or less.

One or more of these additives described above may be contained. In general, an amount of the additives is 20 mol % or less, preferably 15 mol % or less, and more preferably 10 mol % or less with respect to a total amount of elements serving as a main component. By using the additive, it is easy to improve various characteristics to diversify the configuration and function. Also in the case of a composite oxide containing these other elements, it is preferable that the composite oxide has an ABO₃ perovskite structure.

In the present description, the “perovskite composite oxide containing K, Na, and Nb” is “a composite oxide having an ABO₃ perovskite structure containing K, Na, and Nb”, and is not limited to only a composite oxide having an ABO₃ perovskite structure containing K, Na, and Nb. That is, in the present description, the “perovskite composite oxide containing K, Na, and Nb” includes a piezoelectric material represented as a mixed crystal containing a composite oxide having an ABO₃ perovskite structure containing K, Na, and Nb (for example, the KNN-based composite oxide shown above) and another composite oxide having an ABO₃ perovskite structure.

The other composite oxide is not limited within the scope of the embodiment, and is preferably a non-lead-based piezoelectric material which does not contain lead (Pb). According to these, the piezoelectric element 300 is excellent in biocompatibility and has low environmental loading.

The second electrode 80 is formed on the piezoelectric layer 70. The second electrode 80 faces the first electrode 60 with the piezoelectric layer 70 interposed between the second electrode 80 and the first electrode 60. A shape of the second electrode 80 is, for example, a layer shape or a thin film shape. A thickness of the second electrode 80 is, for example, 10 nm or more and 200 nm or less. A planar shape of the second electrode 80 is not particularly limited as long as the piezoelectric layer 70 can be disposed between the first electrode 60 and the second electrode 80 when the second electrode 80 faces the first electrode 60.

As the material for the second electrode 80, for example, the materials listed above as the material for the first electrode 60 can be applied. In order that the ratio of a Young's modulus of the piezoelectric layer 70 to a Young's modulus of the second electrode 80 satisfies the above range, it is preferable to use platinum (Pt) or iridium (Ir) as the material for the second electrode 80.

One of functions of the second electrode 80 is that the second electrode 80 is paired with the first electrode 60 and serves as the other electrode (for example, an upper electrode formed at an upper part of the piezoelectric layer 70) for applying a voltage to the piezoelectric layer 70.

According to the piezoelectric element 300 in a first embodiment described above, the insulation of the piezoelectric layer 70 can be sufficiently improved.

In the above embodiment, the ink jet recording head is described as an example of a liquid ejection head. However, the present disclosure is applicable to liquid ejection heads in general, and is also applicable to a liquid ejection head for ejecting a liquid other than ink. Examples of other liquid ejection heads include various recording heads used in image recording devices such as printers, color material ejection heads used for manufacturing color filters for liquid crystal displays, electrode material ejection heads used for forming electrodes for organic EL displays and field emission displays (FEDs), and bioorganic material ejection heads used for manufacturing biochips.

The present disclosure is not limited to the piezoelectric element mounted on the liquid ejection head, and can also be applied to a piezoelectric element mounted on another piezoelectric element application device. Examples of the piezoelectric element application device include an ultrasonic device, a motor, a pressure sensor, a pyroelectric element, and a ferroelectric element. Completed bodies using these piezoelectric element application devices, for example, an ejection device of a liquid or the like using an ejection head for the liquid or the like, an ultrasonic sensor using the ultrasonic device, a robot using the motor as a driving source, an IR sensor using the pyroelectric element, and a ferroelectric memory using the ferroelectric element are also in the piezoelectric element application device.

In particular, the piezoelectric element according to the present disclosure is suitable as a piezoelectric element to be mounted on a sensor. Examples of the sensor include a gyro sensor, an ultrasonic sensor, a pressure sensor, and a speed and acceleration sensor. When the piezoelectric element according to the present disclosure is applied to a sensor, for example, a voltage detection unit which detects a voltage output from the piezoelectric element 300 is provided between the first electrode 60 and the second electrode 80 to form the sensor. In a case of such a sensor, when the piezoelectric element 300 is deformed due to some external change (change in physical quantity), a voltage is generated according to the deformation. Various physical quantities can be detected by detecting the voltage with the voltage detection unit.

Next, an example of a method for producing the piezoelectric element 300 will be described. Although a case where the piezoelectric layer 70 is produced by a chemical solution method (wet method) is described below, a method for producing the piezoelectric layer 70 is not limited to the wet method, and may be a gas phase method.

First, the substrate (silicon substrate) 10 is prepared, and by thermally oxidizing the substrate 10, the elastic film 51 made of silicon dioxide (SiO₂) is formed at a surface of the substrate 10.

Next, a zirconium film is formed on the elastic film 51 by a sputtering method, a vapor deposition method, or the like, and the zirconium film is thermally oxidized to obtain the insulator film 52 made of zirconium oxide (ZrO₂). In this way, the diaphragm 50 including the elastic film 51 and the insulator film 52 is formed on the substrate 10.

Next, the adhesion layer 56 made of metal titanium (Ti) is formed on the insulator film 52. The adhesion layer 56 can be formed by a sputtering method, or the like. Next, the first electrode 60 made of platinum (Pt) is formed on the adhesion layer 56. The first electrode 60 can be appropriately selected according to an electrode material, and can be formed by vapor phase deposition by a sputtering method, a vacuum deposition method (PVD method), a laser ablation method, or the like, or liquid phase deposition by a spin coating method or the like.

Next, the seed layer 57 is formed on the first electrode 60. The seed layer 57 can be formed by, for example, a chemical solution method (wet method) of obtaining a metal oxide by applying and drying a solution containing a metal complex (precursor solution), and then performing firing at a high temperature. Examples of a material for the seed layer 57 include various metals such as titanium, nickel, iridium, and platinum, and oxides thereof.

Next, a resist having a predetermined shape is formed on the first electrode 60 as a mask, and the adhesion layer 56, the first electrode 60, and the seed layer 57 are simultaneously patterned. Patterning of the adhesion layer 56, the first electrode 60, and the seed layer 57 can be performed by, for example, dry etching such as reactive ion etching (RIE) or ion milling, or wet etching using an etchant. Shapes of the adhesion layer 56, the first electrode 60, and the seed layer 57 in the patterning are not particularly limited.

Next, a plurality of layers of piezoelectric films are formed on the first electrode 60.

The piezoelectric layer 70 is implemented by the plurality of piezoelectric films. The piezoelectric layer 70 can be formed by, for example, a chemical solution method (wet method) of obtaining a metal oxide by applying and drying a solution containing a metal complex (precursor solution), and then performing firing at a high temperature. In addition, the piezoelectric layer 70 can be formed by a laser ablation method, a sputtering method, a pulse laser deposition method (PLD method), a chemical vapor deposition (CVD) method, an aerosol deposition method, or the like. In the embodiment, it is preferable to use a wet method (liquid phase method) from the viewpoint of orienting orientation of the piezoelectric layer 70 in a (100) direction and increasing the Young's modulus of the piezoelectric layer 70.

Here, the wet method (liquid phase method) is a method for deposition by a chemical solution method such as a MOD method or a sol-gel method, and is a concept distinguished from a gas phase method such as a sputtering method. In the embodiment, a gas phase method may be used as long as the piezoelectric layer 70 can be formed in which the orientation is oriented in the (100) direction.

For example, the piezoelectric layer 70 formed by a wet method (liquid phase method) includes a plurality of piezoelectric films 74 formed by a series of steps including a step of applying a precursor solution and forming a precursor film (applying step), a step of drying the precursor film (drying step), a step of heating and degreasing the dried precursor film (degreasing step), and a step of firing the degreased precursor film (firing step). That is, the piezoelectric layer 70 is formed by repeating a series of steps from the applying step to the firing step a plurality of times. In the series of steps described above, the firing step may be performed after repeating the steps from the applying step to the degreasing step a plurality of times.

A specific procedure for forming the piezoelectric layer 70 by a wet method (liquid phase method) is, for example, as follows.

First, a precursor solution containing a predetermined metal complex is prepared. The precursor solution is obtained by dissolving or dispersing a metal complex capable of forming a composite oxide containing K, Na, and Nb by firing in an organic solvent. At this time, a metal complex containing an additive such as Mn, Li, or Cu may be further mixed. By mixing the metal complex containing Mn, Li, or Cu with the precursor solution, it is possible to further increase the insulation of the obtained piezoelectric layer 70. By mixing a polyether material in the precursor solution, a carbon concentration in the obtained piezoelectric film can be reduced.

Examples of a metal complex containing potassium (K) include potassium 2-ethylhexanoate and potassium acetate. Examples of a metal complex containing sodium (Na) include sodium 2-ethylhexanoate and sodium acetate. Examples of a metal complex containing niobium (Nb) include niobium 2-ethylhexanoate and pentaethoxyniobium. When Mn is added as the additive, examples of the metal complex containing Mn include manganese 2-ethylhexanoate. When Li is added as the additive, examples of the metal complex containing Li include lithium 2-ethylhexanoate. At this time, two or more kinds of metal complexes may be used in combination. For example, potassium 2-ethylhexanoate and potassium acetate may be used in combination as the metal complex containing potassium (K). Examples of a solvent include 2-n-butoxyethanol, n-octane, and a mixed solvent thereof. The precursor solution may contain an additive which stabilizes dispersion of the metal complex containing K, Na, and Nb. Examples of such additives include 2-ethylhexanoic acid.

The precursor solution is applied onto the substrate 10 on/above which the elastic film 51, the insulator film 52, and the first electrode 60 are formed to form a precursor film (applying step).

Next, the precursor film is heated at a predetermined temperature, for example, about 130° C. to 250° C. and is dried for a certain period of time (drying step).

Next, the dried precursor film is heated to a predetermined temperature, for example, 250° C. to 450° C., and is held at this temperature for a certain period of time to perform degreasing (degreasing step).

Examples of a heating device used in the drying step, the degreasing step, and the firing step include a rapid thermal annealing (RTA) device which performs heating by irradiation with an infrared lamp, and a hot plate. The above steps are repeated a plurality of times to form the piezoelectric layer 70 including a plurality of layers of piezoelectric films. In a series of steps from the applying step to the firing step, the firing step may be performed after repeating the steps from the applying step to the degreasing step a plurality of times.

Before and after the second electrode 80 is formed on the piezoelectric layer 70, a reheat treatment (post-annealing) may be performed in a temperature range of 600° C. to 800° C. as necessary. By performing the post-annealing thus, a good interface between the piezoelectric layer 70 and the first electrode and a good interface between the piezoelectric layer 70 and the second electrode 80 can be formed. Crystallinity of the piezoelectric layer 70 can be improved, and the insulation of the piezoelectric layer 70 can be further increased.

After the firing step, the piezoelectric layer 70 implemented with a plurality of piezoelectric films is patterned into a shape as shown in FIG. 5. Patterning can be performed by dry etching such as reactive ion etching or ion milling, or wet etching using an etchant.

Thereafter, the second electrode 80 is formed on the piezoelectric layer 70. The second electrode 80 can be formed by a similar method as the first electrode 60.

By the above steps, the piezoelectric element 300 including the first electrode 60, the piezoelectric layer 70, and the second electrode 80 is produced.

### EXAMPLES

Hereinafter, the present disclosure will be described in more detail with reference to Examples, and the present disclosure is not limited to Examples.

### Example 1

First, a surface of a silicon substrate (6 inches) serving as the substrate was thermally oxidized, and an elastic film made of silicon dioxide was formed on the substrate. Further, a zirconium film was formed on the elastic film by a sputtering method, and the zirconium film was thermally oxidized to form an insulator film made of zirconium oxide (ZrO₂). In this way, a diaphragm including the elastic film and the insulator film was formed on the substrate.

Next, an adhesion layer made of titanium (Ti) was formed on the diaphragm by a sputtering method, and a first electrode was further formed on the adhesion layer by a sputtering method. The first electrode is formed by sequentially stacking a layer containing platinum (Pt) and a layer containing iridium (Ir) on/above the adhesion layer.

Next, a seed layer (orientation control layer) was formed on the first electrode by the following procedure.

First, a propionic acid solution of bismuth, iron, titanium, and lead was used to prepare Bi:Pb:Fe:Ti=110:10:50:50. The solution was applied onto the first electrode by a spin coating method. Thereafter, the applied solution was dried/degreased at 350° C. using a hot plate, and was heated at 650° C. for 3 minutes using rapid thermal annealing (RTA), and a seed layer (orientation control layer) was formed.

Next, a piezoelectric layer was formed on the first electrode by the following procedure.

First, a precursor solution containing potassium 2-ethylhexanoate, sodium 2-ethylhexanoate, lithium 2-ethylhexanoate, niobium 2-ethylhexanoate, and manganese 2-ethylhexanoate was used to prepare K_{0.51}Na_{0.49}Li_{0.077}Nb_{0.99}Mn_{0.01}Oₓ, the mixture was applied onto the seed layer by a spin coating method, and a precursor film was formed (applying step).

Thereafter, the precursor film was dried at 180° C. (drying step), and then was degreased at 380° C. for 3 minutes (degreasing step).

Next, the degreased precursor film was subjected to a heat treatment at 700° C. for 3 minutes using rapid thermal annealing (RTA), and a piezoelectric film was formed (firing step). A temperature increase rate in the firing step was 10° C./sec. The steps from the applying step to the firing step were repeated five times to produce a piezoelectric layer made of a plurality of piezoelectric films and having a total film thickness of 400 nm.

Here, a part of the obtained piezoelectric layer was cut out as a sample for a SIMS analysis.

Finally, a second electrode made of platinum (Pt) was formed on the remaining piezoelectric layer by a sputtering method, in a similar manner as the first electrode, and a piezoelectric element was obtained.

### Example 2

Example 2 was similar as Example 1 except that a composition of the piezoelectric layer was K_{0.51}Na_{0.49}Li_{0.077}Nb_{0.984}Mn_{0.01}Cu_{0.006}Oₓ.

### Example 3

Example 3 was similar as Example 2 except that the heating temperature in the firing step was 800° C. and the temperature increase rate was 60° C./sec.

### Example 4

Example 4 was similar as Example 1 except that a polyether material was added to the precursor solution.

### Comparative Example 1

Comparative Example 1 was similar as Example 1 except that the composition of the piezoelectric layer was K_{0.5406}Na_{0.5194}Nb_{0.99}Mn_{0.01}Oₓ.

For each of Examples and Comparative Examples described above, measurement of carbon and oxygen contents (SIMS) and measurement of a leakage current were performed.

### Measurement of Carbon and Oxygen Contents (SIMS)

The carbon and oxygen contents of the sample for the SIMS analysis were measured along a thickness direction by SIMS. Specifically, a secondary ion mass spectrometry (SIMS) apparatus (IMS-7f sector type, manufactured by CAMECA) was used. Primary ions were raster-scanned with Cs+of 15 keV at a beam current of 10 nA of 100 μm square, and negative secondary ions were detected from a center of 33 pmp. An electron gun was used to prevent charge-up.

### Leakage Current Measurement

A leakage current of the obtained piezoelectric element was measured using a microammeter (4140B, manufactured by Hewlett-Packard Company). As measurement conditions, delay time was set to 60 seconds, first electrode side was set to drive, and a leakage current at an electric field intensity of 500 kV/cm was measured.

The above measurement results are shown in Table 1. “Oxygen intensity” in Table 1 is an oxygen intensity (cps) at a position where a maximum carbon intensity (cps) in the piezoelectric layer was detected. “E-0x” in “leakage current amount” and “ratio of carbon intensity to oxygen intensity” in Table 1 represents “x 10^{-x}”. For example, “2.5E-07” means “2.5×10⁻⁷”.

TABLE 1

| | | | | | Compar- |
|---|---|---|---|---|---|
| | | | | | ative |
| | Example 1 | Example 2 | Example 3 | Example 4 | Example 1 |
| Maximum | 8050.3 | 4321.8 | 9181.16 | 10312 | 16696.3 |
| carbon | | | | | |
| intensity in | | | | | |
| piezoelectric | | | | | |
| layer | | | | | |
| Oxygen | 1164260 | 1376180 | 1398680 | 1131780 | 1192410 |
| intensity | | | | | |
| Leakage | 2.5E−07 | 2.5E−07 | 1.1E−04 | 2.6E−04 | 6.3E−02 |
| current | | | | | |
| amount | | | | | |
| (A/cm²) | | | | | |
| Ratio of | 6.9E−03 | 3.1E−03 | 6.6E−03 | 9.1E−03 | 1.4E−02 |
| carbon | | | | | |
| intensity to | | | | | |
| oxygen | | | | | |
| intensity | | | | | |

### Test Results

As shown in Table 1, in Examples 1 to 4, a ratio of the oxygen intensity to the carbon intensity in the piezoelectric layer can be sufficiently reduced, and the leakage current amount can be significantly reduced.

What is claimed is:

1. A piezoelectric element comprising:
a substrate;
a first electrode formed on the substrate;
a piezoelectric layer formed on the first electrode; and
a second electrode formed on the piezoelectric layer, wherein
the piezoelectric layer contains potassium, sodium, niobium, oxygen, and carbon, and
in secondary ion mass spectrometry in the piezoelectric layer, a ratio of a maximum intensity of carbon to a maximum intensity of oxygen is 3.1×10⁻³ or more and 9.1×10⁻³ or less.

2. The piezoelectric element according to claim 1, wherein
the piezoelectric layer includes a plurality of piezoelectric films stacked in a direction from the first electrode toward the second electrode.

3. The piezoelectric element according to claim 1, wherein
the piezoelectric layer contains lithium.

4. The piezoelectric element according to claim 1, wherein
the piezoelectric layer contains a first transition metal.

5. The piezoelectric element according to claim 4, wherein
the piezoelectric layer contains two or more kinds of the first transition metals, and
a total content of the first transition metals in the piezoelectric layer is 5 mol % or less.

6. The piezoelectric element according to claim 1, wherein
a seed layer is provided between the first electrode and the piezoelectric layer, and
crystal orientation of a surface of the piezoelectric layer is preferentially oriented to a (100) plane.

7. A piezoelectric element application device comprising:
the piezoelectric element according to claim 1.
